(19) United States
(12) Patent Application Publication
(10) Pub. No.: US 2013/0127690 A1
(43) Pub. Date: May 23, 2013

(54) ELECTRONIC APPARATUS AND DISPLAY APPARATUS

(71) Applicant: Tzeng-Shii Tsai, Hsinchu County (TW)

(72) Inventor: Tzeng-Shii Tsai, Hsinchu County (TW)

(73) Assignee: INDUSTRIAL TECHNOLOGY RESEARCH INSTITUTE, Hsinchu (TW)

(21) Appl. No.: 13/439,745

(22) Filed: Apr. 4, 2012

(30) Foreign Application Priority Data
Nov. 18, 2011 (TW) TW100142226

(51) Int. Cl. G09G 3/20; H05K 1/18

(52) U.S. Cl. 345/55; 174/260

(57) ABSTRACT

An embodiment of the disclosure provides an electronic apparatus including: a shape memory alloy substrate; and an electronic device disposed on the shape memory alloy substrate, wherein the shape memory alloy substrate has moisture resistance and oxygen resistance which are better than that of plastic substrates, and has impact-resistance and high stability.

### CROSS REFERENCE TO RELATED APPLICATIONS

This Application claims priority of Taiwan Patent Application No. 100142226, filed on Nov. 18, 2011, the entirety of which is incorporated by reference herein.

### BACKGROUND

1. Field of the Disclosure

The present disclosure relates to an electronic device, and in particular relates to an electronic apparatus and a display apparatus using a shape memory alloy as a substrate.

2. Description of the Related Art

With progress of display technologies and information products, displays have moved to the flat panel display age from the traditional cathode ray tube age. Compared to traditional rigid glass flat panel displays, flexible displays are thinner, lighter, flexible, impact-resistant, safe, and not limited by condition and space, so the potential new trend for development of displays in the next age is towards flexible displays.

A flexible thin film transistor substrate is one of the important devices of a flexible display, and selection and development of materials of the substrate are important issues in the development of the flexible display. At present, the flexible substrate may be a plastic substrate., While the plastic substrate is light, thin, impact-resistant, and low cost, it suffers from a lack of high temperature resistance, moisture resistance, and oxygen resistance, and high thermal expansion coefficients. Furthermore, flexible electronic apparatuses or flexible display apparatuses may have a bent shape, a shape like a roll, or a flat shape, etc., and may change shapes for different application conditions (or for different application needs). Thus, suitable materials for forming the substrate are needed.

### BRIEF SUMMARY

An embodiment of the disclosure provides an electronic apparatus which includes: a shape memory alloy substrate; and an electronic device disposed on the shape memory alloy substrate.

An embodiment of the disclosure provides a display apparatus, includes: a shape memory alloy substrate; a pixel circuit layer disposed on the shape memory alloy substrate; and a display element layer disposed on the pixel circuit layer.

A detailed description is given in the following embodiments with reference to the accompanying drawings.

### BRIEF DESCRIPTION OF THE DRAWINGS

The present disclosure can be more fully understood by reading the subsequent detailed description and examples with references made to the accompanying drawings, wherein:

FIG. 1 is a cross-sectional view of an electronic apparatus according to an embodiment of the present disclosure;

FIG. 2 is a cross-sectional view of an electronic apparatus according to another embodiment of the present disclosure;

FIG. 3A is a cross-sectional view of an electronic apparatus according to an embodiment of the present disclosure;

FIG. 3B is a top view of the mesh structure shown in FIG. 3A;

FIG. 4 is a cross-sectional view of an electronic apparatus according to an embodiment of the present disclosure;

FIG. 5 is a top view of an electronic apparatus according to an embodiment of the present disclosure;

FIG. 6 is a top view of an electronic apparatus according to another embodiment of the present disclosure;

FIG. 7 is a cross-sectional view of an electronic apparatus according to an embodiment of the present disclosure;

FIG. 8 is a bottom view of the electronic apparatus shown in FIG. 7;

FIG. 9 is a cross-sectional view of a display apparatus according to an embodiment of the present disclosure;

FIG. 10 is a cross-sectional view of a display apparatus according to another embodiment of the present disclosure;

FIG. 11 is a top view of a display apparatus according to an embodiment of the present disclosure;

FIG. 12 is a cross-sectional view of the display apparatus along the line I-I′ in FIG. 11;

FIG. 13 is a cross-sectional view of a display apparatus according to an embodiment of the present disclosure; and

FIG. 14 is a bottom view of the electronic apparatus shown in FIG. 13.

### DETAILED DESCRIPTION

The following description is one of of the contemplated mode of carrying out the disclosure. This description is made for the purpose of illustrating the general principles of the disclosure and should not be taken in a limiting sense. The scope of the disclosure is best determined by reference to the appended claims.

It is understood, that the following disclosure provides many different embodiments, or examples, for implementing different features of the disclosure. Specific examples of components and arrangements are described below to simplify the present disclosure. These are, of course, merely examples and are not intended to be limiting. In addition, the present disclosure may repeat reference numbers and/or letters in the various examples. This repetition is for the purpose of simplicity and clarity and does not in itself dictate a relationship between the various embodiments and/or configurations discussed. Furthermore, descriptions of a first layer “on,” “overlying,” (and like descriptions) a second layer, include embodiments where the first and second layers are in direct contact and those where one or more layers are interposing the first and second layers.

The present disclosure uses a shape memory alloy to form a substrate of a flexible electronic apparatus (or a flexible display apparatus), wherein the shape memory alloy has moisture resistance and oxygen resistance which are better than that of plastic substrates, and has impact-resistance and high stability. The shape memory alloy has plasticity in room temperature, so the shape memory alloy may be bent to be shaped according to application needs, and the shape memory alloy may be recoverable to its original shape (e.g. a flat shape) or the like (e.g. a slightly bent shape) by heating the shape memory alloy (at a temperature higher than room temperature). The present disclosure disposes the electronic device directly on the shape memory alloy substrate instead of on a general substrate (e.g. a glass substrate or a plastic substrate) and then being attached to a shape memory alloy substrate. Accordingly, the present disclosure may reduce the total thickness of the flexible electronic apparatus (or the flexible display apparatus).

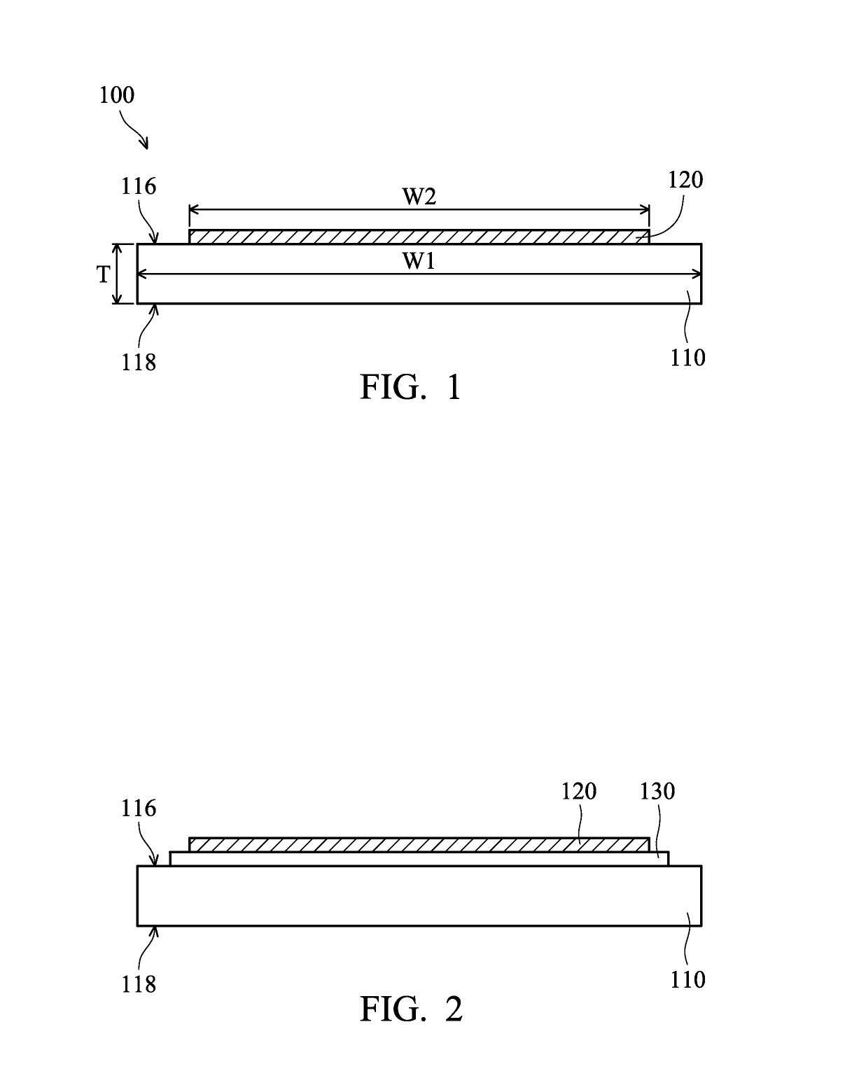

FIG. 1 is a cross-sectional view of an electronic apparatus according to an embodiment of the present disclosure. Referring to FIG. 1, in the present embodiment, an electronic apparatus 100 includes a shape memory alloy substrate 110 and an electronic device 120 disposed on a surface 116 of the shape memory alloy substrate 110. The electronic device 120 and the shape memory alloy substrate 110 are electrically insulated from each other. For example, the electronic device 120 is encapsulated by an insulating layer, the conductivity of the electronic device 120 is far higher than that of the shape memory alloy substrate 110, or the shape memory alloy substrate 110 is covered by an insulating layer.

It should be noted that, the present embodiment disposes the electronic device 120 directly on the shape memory alloy substrate 110 to take the shape memory alloy substrate 110 as the substrate directly carrying the electronic device 120 without disposing an additional electronic device substrate thereon, which reduces the total thickness of the electronic apparatus 100.

A thickness T of the shape memory alloy substrate 110 is, for example, about 5 μm to 5 mm. In one embodiment, the thickness T of the shape memory alloy substrate 110 is about 20 μm to 200 μm. A maximum-width W1 of the shape memory alloy substrate 110 is larger than or equal to a maximum-width W2 of the electronic device 120. That is to say, the size of the shape memory alloy substrate 110 is larger than or equal to the size of the electronic device 120. In one embodiment, the shape memory alloy substrate 110 has a surface 118 which is an exposed surface located at a side of the shape memory alloy substrate 110 opposite to the electronic device 120, wherein there is no device disposed on the exposed surface. In another embodiment, the electronic device 120 may dispose on both surfaces of the shape memory alloy substrate 110.

The material of the shape memory alloy substrate 110 is, for example, a one-way type memory alloy, a two-way type memory alloy, or a pseudo-elastic type memory alloy. When the material of the shape memory alloy substrate 110 is the one-way type memory alloy, the shape memory alloy substrate 110 may be set (or trained) in a flat shape or a bent shape. When the shape memory alloy substrate 110 is set in the bent shape, the shape memory alloy substrate 110 may be flatly fixed on the stage (not shown) by using clips or by evacuation in the process of manufacturing the electronic device 120.

The material of the shape memory alloy substrate 110 is, for example, a nickel-based alloy, a copper-based alloy, a ferrous-base alloy, a gold-based alloy, or combinations thereof, or other suitable alloys. Specifically, the material of the shape memory alloy substrate 110 may be a nickel-titanium alloy, a nickel-aluminum alloy, a copper-aluminum-nickel alloy, a copper-aluminum-zinc alloy, a copper-gold-zinc alloy, a copper-tin alloy, a copper-zinc alloy, a silver-cadmium alloy, a gold- cadmium alloy, or combinations thereof. The shape memory alloy substrate 110 may be formed by, for example, rolling of an ingot into a plate form or depositing of a thin film on a carrying film (such as using a sputtering process or a vapor deposition process).

In one embodiment, before the electronic device 120 is disposed on the shape memory alloy substrate 110, a planarization process may be performed on the surfaces 116, and 118 of the shape memory alloy substrate 110, wherein the planarization method includes milling, polishing, wet etching, dry etching, or disposing a planar film by plating, coating or deposition on the surfaces 116, and 118, wherein the planar film is formed of metal, polymer, oxides, or nitrides. The electronic device 120 is formed by using, for example, thin-film deposition processes, photo-lithography processes, and etching processes, or by using screen printing processes, and inkjet printing processes, or other thick film processes. The electronic device 102 may also include additional components, such as passive components (resistors, capacitors and inductors) or IC chips assembled by surface mount technology (SMT) or insertion method.

FIG. 2 is a cross-sectional view of an electronic apparatus according to another embodiment of the present disclosure. Referring to FIG. 2, in one embodiment, an insulating layer 130 may be optionally disposed on the shape memory alloy substrate 110 and located between the shape memory alloy substrate 110 and the electronic device 120 to electrically insulate the shape memory alloy substrate 110 from the electronic device 120. The insulating layer 130 includes, for example, oxides (e.g. silicon oxide or aluminum oxide), nitrides (e.g. silicon nitride or aluminum nitride), or polymer materials (e.g. polyimide, polyurethane or acrylic). The manufacturing method of the insulating layer 130 includes physical vapor deposition (PVD), chemical vapor deposition (CVD), printing, diping or spin-coating methods.

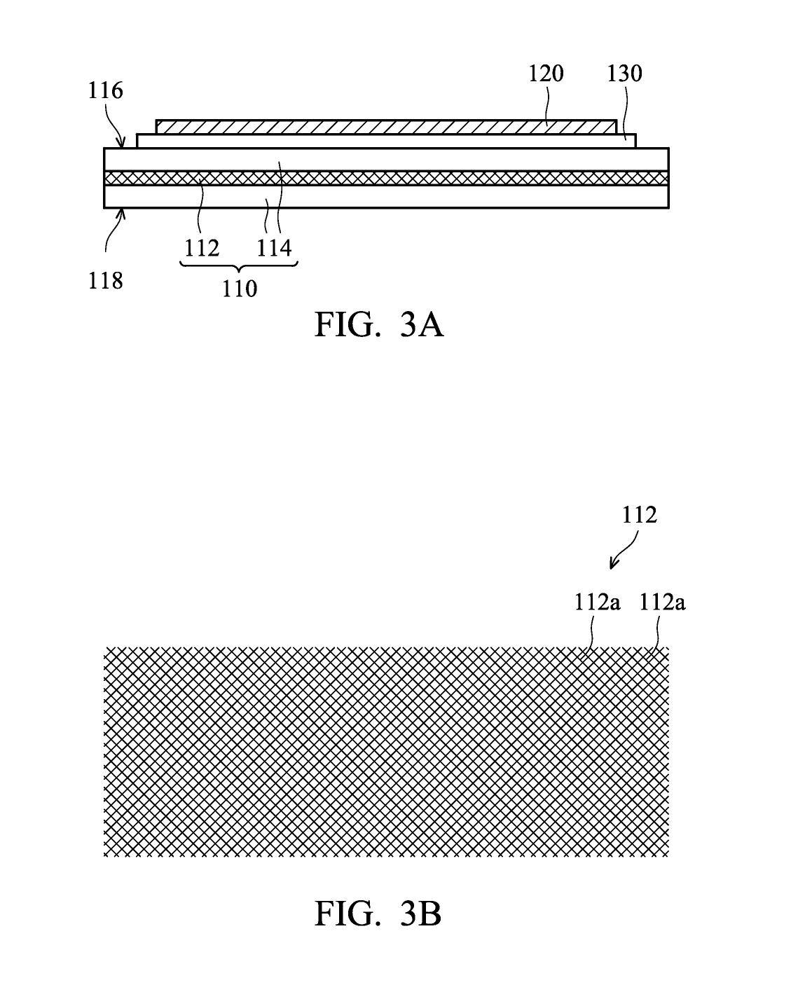

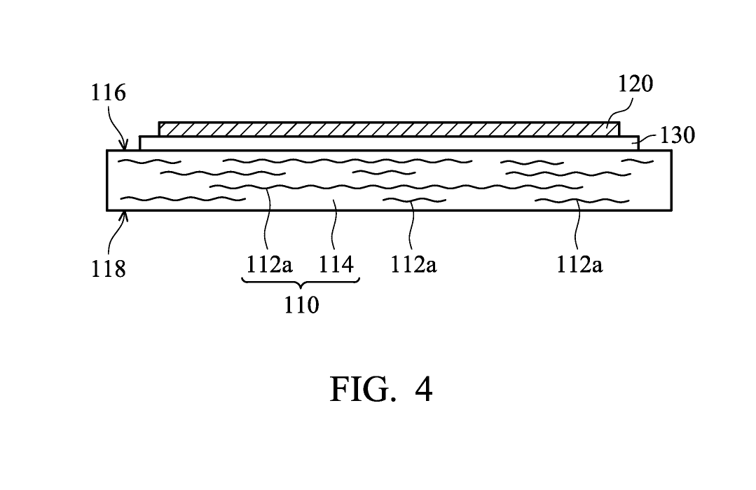

FIG. 3A is a cross-sectional view of an electronic apparatus according to an embodiment of the present disclosure. FIG. 3B is a top view of the mesh structure shown in FIG. 3A. Referring to FIG. 3A and FIG. 3B, in one embodiment, the shape memory alloy substrate 110 may be a composite substrate, and the composite substrate includes a polymer layer 114 and a plurality of shape memory alloy fibers 112a in the polymer layer 114. The shape memory alloy fibers 112a may constitute a mesh structure 112 encapsulated by the polymer layer 114. Although FIG. 3 merely depicts a layer of the mesh structure 112, in other embodiments not shown, the composite substrate may include layers of the mesh structure 112. The shape memory alloy fibers 112a may be embedded in the polymer matrix of the polymer layer 114 in a weave type or in a non-woven cloth type. FIG. 4 is a cross-sectional view of an electronic apparatus according to an embodiment of the present disclosure. Referring to FIG. 4, in one embodiment, the shape memory alloy fibers 112a may be dispersed in the polymer layer 114.

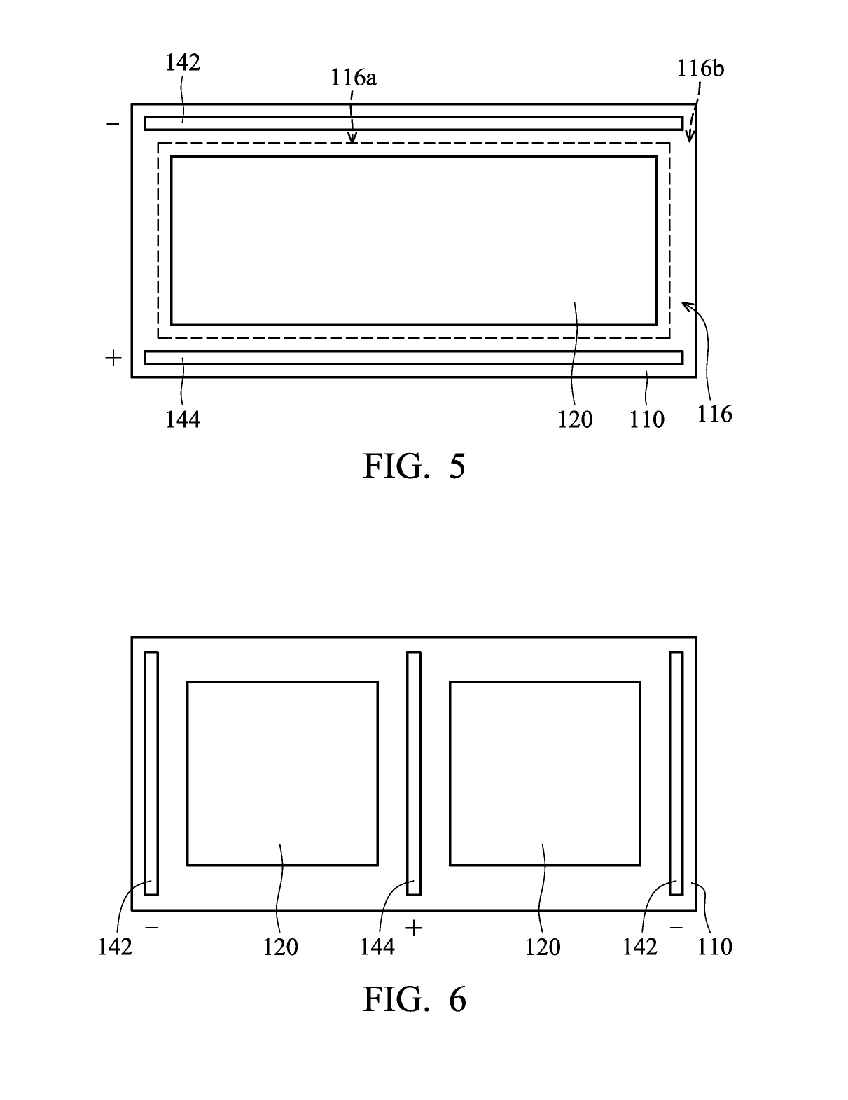

FIG. 5 is a top view of an electronic apparatus according to an embodiment of the present disclosure. Referring to FIG. 5, in one embodiment, a first heating electrode 142 and a second heating electrode 144 may be disposed on the shape memory alloy substrate 110, and are separated from each other, and are electrically connected to each other through the shape memory alloy substrate 110.

The surface 116 of the shape memory alloy substrate 110 has a central area 116a and a peripheral area 116b surrounding the central area 116a. The electronic device 120 may be disposed in the central area 116a. The first heating electrode 142 and the second heating electrode 144 are both located in the peripheral area 116b and are respectively located at two opposite sides of the central area 116a (e.g. up and down sides as shown in FIG. 5 or left and right sides). In one embodiment, the first heating electrode 142, the second heating electrode 144, and a conductive layer of the electronic device 120 may be formed in the same processing step.

In the embodiment, FIG. 5 shows that the first heating electrode 142, the second heating electrode 144, and the electronic device 120 are all located on the same surface 116. That is to say, the first heating electrode 142, the second heating electrode 144, and the electronic device 120 are all located at the same side of the shape memory alloy substrate 110. In other embodiments, the first heating electrode 142 and the second heating electrode 144 may be located on the surface 118 (as shown in FIG. 1). That is to say, the first heating electrode 142, the second heating electrode 144, and the electronic device 120 are respectively located at two opposite sides of the shape memory alloy substrate 110. In another embodiment, two heating electrodes (not shown) may be disposed on the two opposite surfaces 116 and 118 of the shape memory alloy substrate 110.

The first heating electrode 142 and the second heating electrode 144 may be respectively applied with different voltages, such that a current passes through the shape memory alloy substrate 110 connecting between the first heating electrode 142 and the second heating electrode 144, and thereby the shape memory alloy substrate 110 is heated due to the resistance of the shape memory alloy substrate 110. For example, the first heating electrode 142 is applied with a negative voltage, and the second heating electrode 144 is applied with a positive voltage. Alternatively, the first heating electrode 142 and the second heating electrode 144 may be applied with an alternating current.

In actual applications, the shape memory alloy substrate 110 may be bent (e.g. annular electronic apparatuses, such as watches). Then, when the shape memory alloy substrate 110 is needed to be recovered to its original flat shape or the like, the first heating electrode 142 and the second heating electrode 144 may be respectively applied with different voltages to heat the shape memory alloy substrate 110 so as to recover to its original flat shape or the like.

Although FIG. 5 merely depicts two heating electrodes, in other embodiments, three or more than three heating electrodes may be disposed. For example, as shown in FIG. 6, two first heating electrodes 142 and one second heating electrode 144 may be disposed on the shape memory alloy substrate 110, wherein the second heating electrode 144 is located between the two first heating electrodes 142.

In this case, the first heating electrodes 142 and the second heating electrode 144 may be respectively applied with different voltages, such that a current passes through the shape memory alloy substrate 110 connecting between the first heating electrodes 142 and the second heating electrode 144 to heat the shape memory alloy substrate 110.

In one embodiment, when the shape memory alloy substrate 110 is a composite substrate, a portion of the polymer layer 114 may be removed to expose a portion of the shape memory alloy fibers 112a, and the first heating electrode 142 and the second heating electrode 144 may be formed on the exposed shape memory alloy fibers 112a to electrically connect to the shape memory alloy fibers 112a.

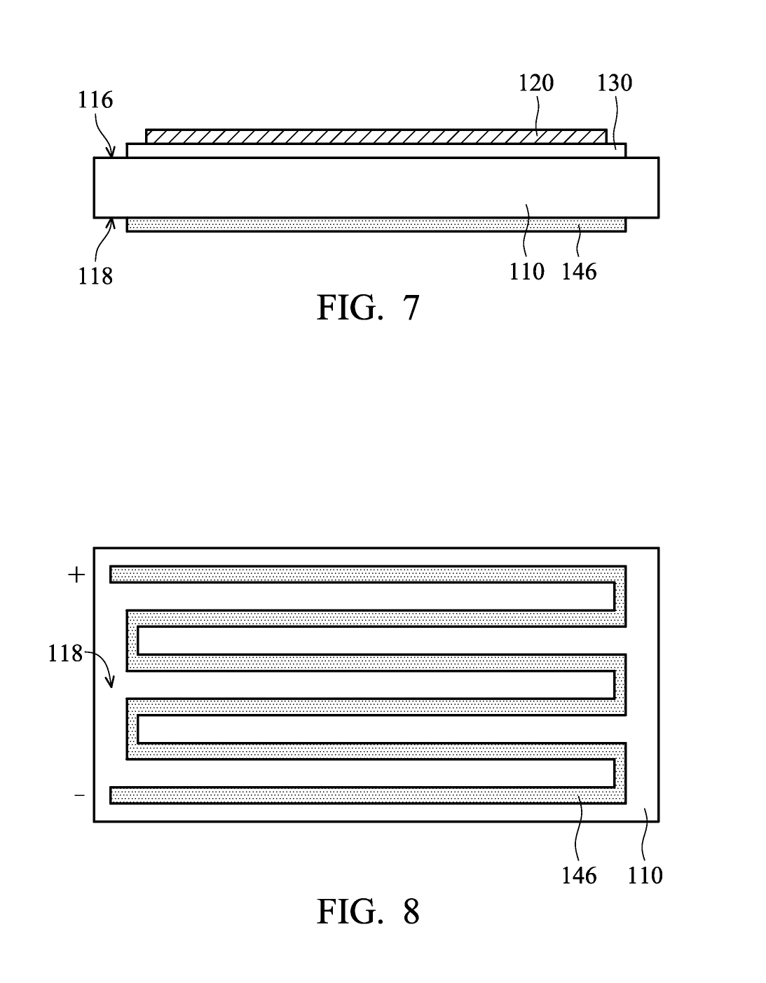

FIG. 7 is a cross-sectional view of an electronic apparatus according to an embodiment of the present disclosure. FIG. 8 is a bottom view of the electronic apparatus shown in FIG. 7. Referring to FIG. 7 and FIG. 8, in one embodiment, a heater 146 may be optionally disposed on the surface 118 of the shape memory alloy substrate 110, wherein the heater 146 is suitable to generate thermal energy to heat the shape memory alloy substrate 110, so that the shape memory alloy substrate 110 recovers to the flat shape or a less bent shape. The heater 146 may be an electronic heater. That is to say, the heater 146 is a heater capable of transferring electronic energy to thermal energy. The heater 146 may be an electric resistance wire or film, wherein the electric resistance wire or film is formed of materials with high electric resistance and high melting temperature (e.g. nickel-chromium alloys or ferrous-chromium-aluminum alloys), and the shape of the electric resistance wire is in, for example, a straight-line shape, a spiral shape, or a bent line shape (as shown in FIG. 8).

In the present embodiment, the electronic device 120 and the heater 146 may be respectively located on the surfaces 116 and 118 of the shape memory alloy substrate 110. In other embodiments, the electronic device 120 and the heater 146 may be both located on the surface 116. When the shape memory alloy substrate 110 is a composite substrate, the heater 146 may be used to recover to the original shape of the shape memory alloy substrate 110.

The heater 146, the first heating electrode 142, and the second heating electrode 144 are optional elements. That is to say, other external apparatuses may be used to heat the shape memory alloy substrate 110, or a shape memory alloy with a pseudo-elastic property is used to form the substrate. When the shape memory alloy substrate 110 with the pseudo-elastic property is used, a mechanical part (not shown) may be used to fix the shape of the shape memory alloy substrate 110, and the shape memory alloy substrate 110 may recover to its original shape by removing the mechanical part.

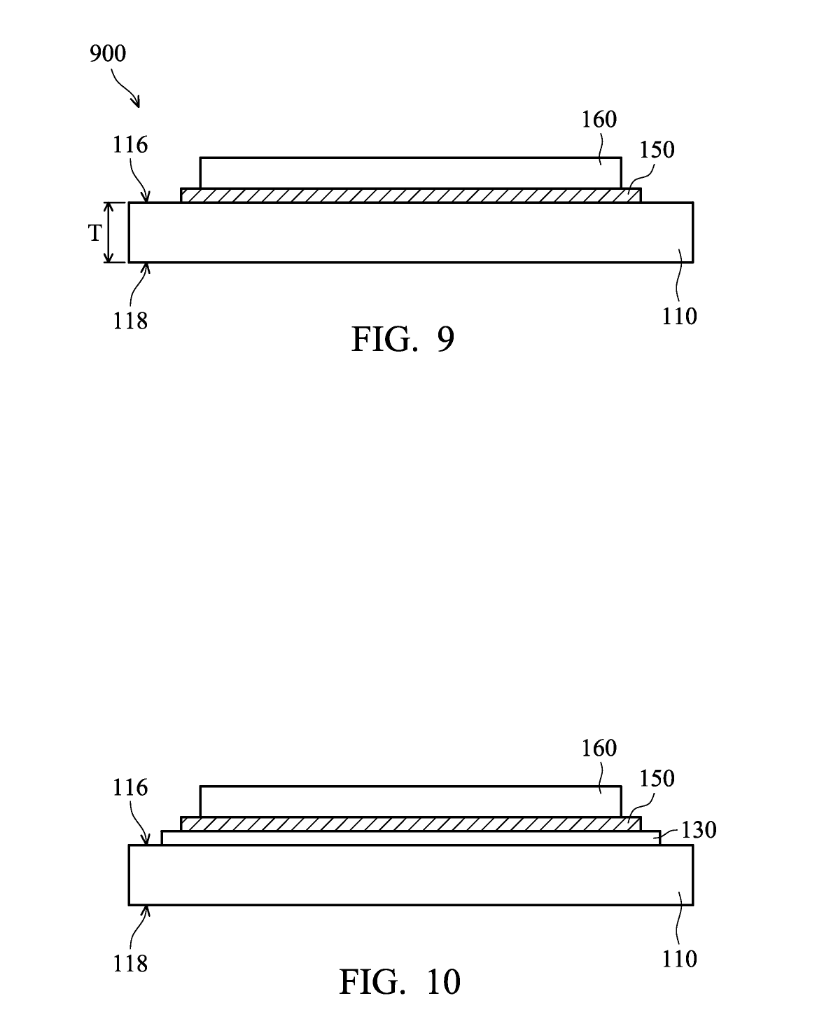

FIG. 9 is a cross-sectional view of a display apparatus according to an embodiment of the present disclosure. Referring to FIG. 9, the display apparatus 900 of the present embodiment includes a shape memory alloy substrate 110, a pixel circuit layer 150, and a display element layer 160, wherein the pixel circuit layer 150 is disposed on the surface 116 of the shape memory alloy substrate 110, and the display element layer 160 is disposed on the pixel circuit layer 150. The pixel circuit layer 150 is insulated from the shape memory alloy substrate 110. The display element layer 160 includes a specific display material layer, and includes the elements required including adhesion layers, reflective layers, alignment layers, color adjustment layers (or color filter), micro-encapsulation films, ribs (or banks), spacers, electrodes for controlling pixels, black matrixes, gas-barrier layers, cover films (or protection films), anti-glare layers and anti-reflect layers, wherein the layers mentioned above may be assembled differently according to different requirements. The display panel of the present embodiment takes a shape memory alloy to form a substrate.

The pixel structure and the display mode of the display element layer 160 may be emissive type or reflective type, for example, an organic light emitting diode (OLED), an electrophoretic display (EPD), a liquid crystal display (LCD), an electrowetting display (EWD), a quick-response liquid powder display (QR-LPD), or combinations thereof, or other display modes, wherein the liquid crystal display may be a micro-encapsulated cholesteric liquid crystal display (ChLCD) or a twisted nematic liquid crystal display (TN-LCD). The pixel circuit layer 150 is, for example, an active-matrix driving circuit layer, a passive-matrix driving circuit layer, a segmented driving circuit layer, or combinations thereof.

A thickness T of the shape memory alloy substrate 110 is, for example, about 5 μm to 5 mm. In one embodiment, the thickness T of the shape memory alloy substrate 110 may be about 20 μm to 200 μm. In one embodiment, the shape memory alloy substrate 110 is a composite substrate, and the material and the structure of the composite substrate of the present embodiment are similar to the composite substrate shown in FIG. 3A or FIG. 4, and thus not repeated herein.

FIG. 10 is a cross-sectional view of a display apparatus according to another embodiment of the present disclosure. Referring to FIG. 10, in one embodiment, an insulating layer 130 may be disposed on the shape memory alloy substrate 110, and between the shape memory alloy substrate 110 and the pixel circuit layer 150 so as to electrically insulate the shape memory alloy substrate 110 from the pixel circuit layer 150.

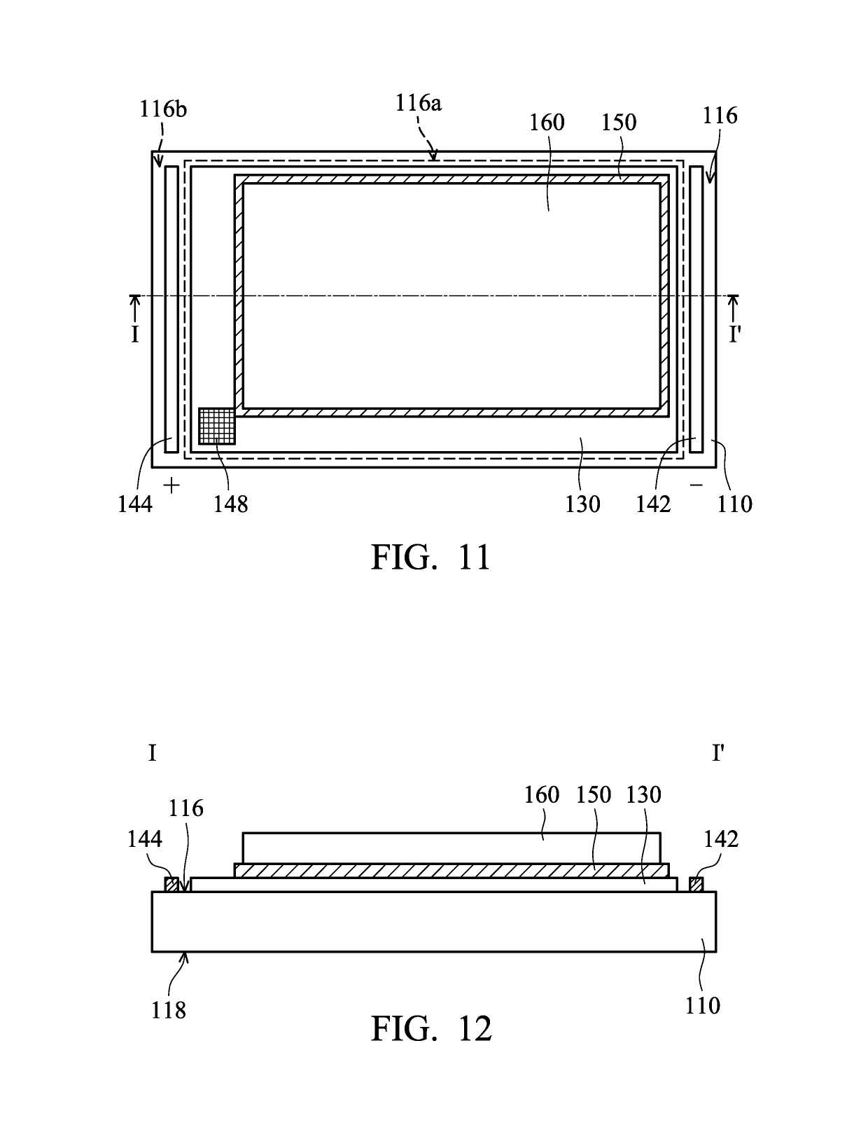

FIG. 11 is a top view of a display apparatus according to an embodiment of the present disclosure. FIG. 12 is a cross-sectional view of the display apparatus along the line I-I′ in FIG. 11. Referring to FIG. 11 and FIG. 12, in one embodiment, a first heating electrode 142, a second heating electrode 144, and a heating controller 148 may be disposed on the shape memory alloy substrate 110, wherein the first heating electrode 142 and the second heating electrode 144 are separated from each other, and electrically connect each other through the shape memory alloy substrate 110. The heating controller 148 may electrically connect the first heating electrode 142 and the second heating electrode 144, and may control the temperature of the shape memory alloy substrate 110 by setting the current and the time parameter, so as to recover to the original memory shape of the shape memory alloy substrate 110. At least one temperature sensor (not shown) may be optionally disposed in a suitable position of the shape memory alloy substrate 110 for the feedback of the temperature variation.

The surface 116 of the shape memory alloy substrate 110 has a central area 116a and a peripheral area 116b surrounding the central area 116a. The pixel circuit layer 150 may be disposed in the central area 116a, and the pixel circuit layer 150 may include thin film transistors and may further include driver integrated circuits (driver ICs), and devices (such as control circuits and power modules) required for displaying images may be disposed on the periphery of the central area 116a (not shown). The first heating electrode 142 and the second heating electrode 144 are both located in the peripheral area 116b and are respectively located at two opposite sides of the central area 116a (e.g. up and down sides or left and right sides as shown in FIG. 11). The usage method of the first heating electrode 142 and the second heating electrode 144 is similar to that of the first heating electrode 142 and the second heating electrode 144 of FIG. 5, and thus not repeated herein.

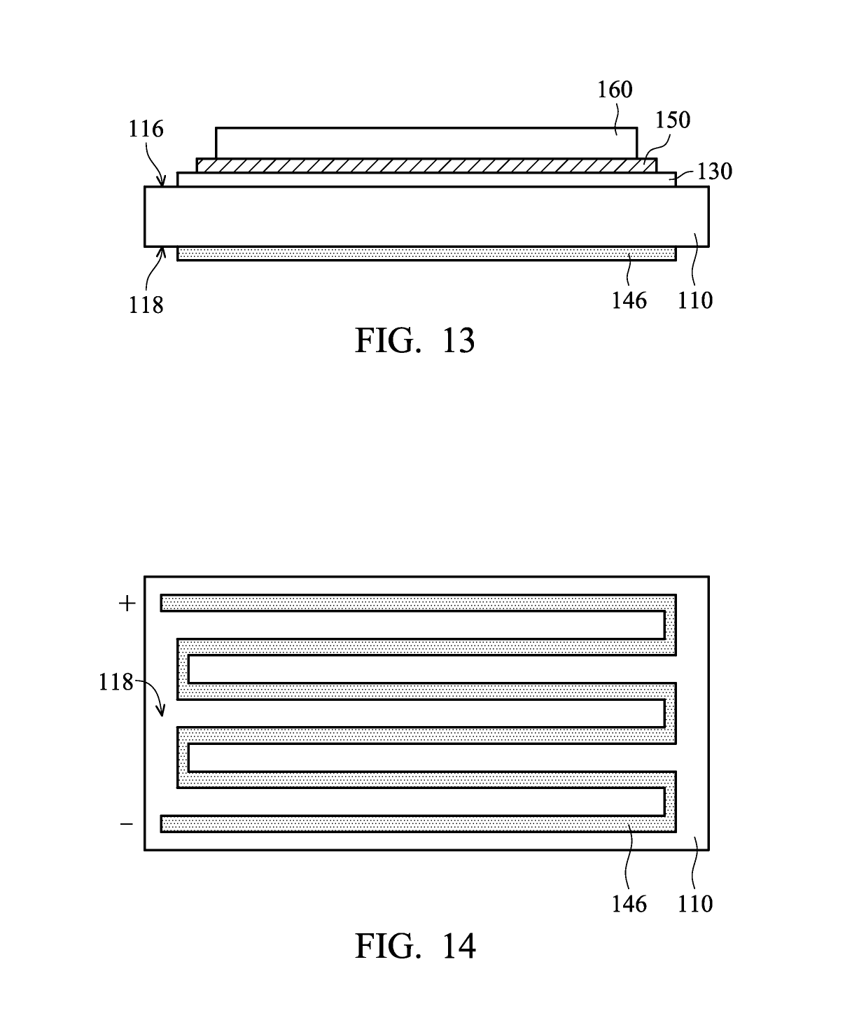

FIG. 13 is a cross-sectional view of a display apparatus according to an embodiment of the present disclosure. FIG. 14 is a bottom view of the electronic apparatus shown in FIG. 13. Referring to FIG. 13 and FIG. 14, in one embodiment, a heater 146 may be disposed on the surface 118 of the shape memory alloy substrate 110. The function, the material, the structure, and the deposition mode of the heater 146 of the present embodiment are similar to the heater 146 of FIG. 8, and thus not repeated herein.

In view of the foregoing, the present disclosure disposes the electronic device (or the pixel circuit layer and the display element layer) directly on the shape memory alloy substrate to take the shape memory alloy substrate as the substrate directly carrying the electronic device (or the pixel circuit layer and the display element layer) without disposing of an additional electronic device substrate (or a display device substrate), which reduces the total thickness of the flexible electronic apparatus (or the flexible display apparatus).

While the invention has been described by way of example and in terms of the preferred embodiments, it is to be understood that the disclosure is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An electronic apparatus, comprising:
a shape memory alloy substrate; and
an electronic device disposed on the shape memory alloy substrate.

2. The electronic apparatus as claimed in claim 1, wherein a thickness of the shape memory alloy substrate is about 5 μm to 5 mm.

3. The electronic apparatus as claimed in claim 2, wherein the thickness of the shape memory alloy substrate is about 20 μm to 200 μm.

4. The electronic apparatus as claimed in claim 1, further comprising:
an insulating layer disposed on the shape memory alloy substrate and between the shape memory alloy substrate and the electronic device.

5. The electronic apparatus as claimed in claim 1, further comprising:
at least one first heating electrode disposed on the shape memory alloy substrate and electrically connected to the shape memory alloy substrate; and
at least one second heating electrode disposed on the shape memory alloy substrate and electrically connected to the shape memory alloy substrate, wherein the second heating electrode is separated from the first heating electrode and electrically connects to the first heating electrode through the shape memory alloy substrate.

6. The electronic apparatus as claimed in claim 5, wherein the shape memory alloy substrate has a surface having a central area and a peripheral area surrounding the central area, and the first heating electrode and the second heating electrode are both located in the peripheral area and are respectively located at two opposite sides of the central area.

7. The electronic apparatus as claimed in claim 1, further comprising:
a heater disposed on the shape memory alloy substrate and adapted to generate thermal energy to heat the shape memory alloy substrate.

8. The electronic apparatus as claimed in claim 1, wherein the shape memory alloy substrate is a composite substrate, and the composite substrate comprises a polymer layer and a plurality of shape memory alloy fibers in the polymer layer.

9. The electronic apparatus as claimed in claim 1, wherein a maximum-width of the shape memory alloy substrate is larger than or equal to a maximum-width of the electronic device.

10. The electronic apparatus as claimed in claim 1, wherein the shape memory alloy substrate has an exposed surface located at a side of the shape memory alloy substrate opposite to the electronic device.

11. A display apparatus, comprising:
a shape memory alloy substrate;
a pixel circuit layer disposed on the shape memory alloy substrate; and
a display element layer disposed on the pixel circuit layer.

12. The display apparatus as claimed in claim 11, wherein the display element layer comprises an organic light emitting diode display, an electrophoretic display, a liquid crystal display, an electrowetting display, a quick-response liquid powder display, or combinations thereof.

13. The display apparatus as claimed in claim 11, wherein the pixel circuit layer is an active matrix driving circuit layer, a passive matrix driving circuit layer, a segmented driving circuit layer, or combinations thereof.

14. The display apparatus as claimed in claim 11, wherein a thickness of the shape memory alloy substrate is about 5 μm to 5 mm.

15. The display apparatus as claimed in claim 14, wherein the thickness of the shape memory alloy substrate is about 20 μm to 200 μm.

16. The display apparatus as claimed in claim 11, further comprising:
an insulating layer disposed on the shape memory alloy substrate and between the shape memory alloy substrate and the pixel circuit layer.

17. The display apparatus as claimed in claim 11, further comprising:
at least one first heating electrode disposed on the shape memory alloy substrate and electrically connected to the shape memory alloy substrate; and
at least one second heating electrode disposed on the shape memory alloy substrate and electrically connected to the shape memory alloy substrate, wherein the second heating electrode is separated from the first heating electrode and electrically connects to the first heating electrode through the shape memory alloy substrate.

18. The display apparatus as claimed in claim 17, wherein the shape memory alloy substrate has a surface having a central area and a peripheral area surrounding the central area, and the first heating electrode and the second heating electrode are both located in the peripheral area and are respectively located at two opposite sides of the central area.

19. The display apparatus as claimed in claim 11, further comprising:
a heater disposed on the shape memory alloy substrate and adapted to generate thermal energy to heat the shape memory alloy substrate.

20. The display apparatus as claimed in claim 11, wherein the shape memory alloy substrate is a composite substrate, and the composite substrate comprises a polymer layer and a plurality of shape memory alloy fibers in the polymer layer.
